(19) United States
(12) Patent Application Publication
(10) Pub. No.: US 2017/0176539 A1
(43) Pub. Date: Jun. 22, 2017

(54) Wireless Capable Battery

(71) Applicant: CenturyLink Intellectual Property LLC, Denver, CO (US)

(72) Inventor: Keith E. Younger, Overland Park, KS (US)

(21) Appl. No.: 15/043,931

(22) Filed: Feb. 15, 2016

Related U.S. Application Data
(60) Provisional application No. 62/268,448, filed on Dec. 16, 2015.

(51) Int. Cl. G01R 31/36; H04L 29/08; H04B 1/3883

(52) U.S. Cl. CPC G01R 31/3651; H04B 1/3883; H04L 67/10

(57) ABSTRACT

Novel tools and techniques might provide for implementing wireless capable batteries or wireless capable battery testers. In various embodiments, a wireless capable battery or wireless capable battery tester might receive, from one or more sensors of the wireless capable battery tester, one or more measured characteristics (e.g., voltage, current, temperature, location, etc.) of a battery that is installed in equipment (e.g., telecommunications equipment, vehicle, consumer electronics, lighting systems, solar-powered devices, etc.), and might wirelessly send the measured characteristics to one or more user devices. In some cases, the measured characteristics might be sent to a server over a network for analysis prior to sending wirelessly to the user devices. The user devices might receive the measured characteristics, and might display, in a user interface of an app or web portal, the measured characteristics (in some cases, along with recommended courses of action to take, such as replacement, recharge, etc.).

### CROSS-REFERENCES TO RELATED APPLICATIONS

This application claims priority to U.S. Patent Application Ser. No. 62/268,448 (the “'448 application”), filed Dec. 16, 2015 by Keith Younger et al. (attorney docket no. 020370-026601US), entitled, “Bluetooth Capable Battery,” the disclosure of which is incorporated herein by reference in its entirety for all purposes.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to methods, systems, apparatus, and computer software for implementing wireless capable batteries or wireless capable battery testers, and, in particular embodiments, to methods, systems, apparatus, and computer software for implementing integrated wireless capable batteries/testers or enabling wireless communication between a battery and/or a battery tester and a user device.

### BACKGROUND

Batteries are used to operate a number of user devices and equipment, including, but not limited to, telecommunications equipment, vehicles, consumer and other electronics/appliances, lighting systems, and/or the like. Such batteries, however, do not currently offer wireless capability, nor are there existing wireless capable battery testers that are either built in such batteries or external, but connected, to such batteries, and separate from particular devices that do have battery capacity measurement functionality (such as smart phones, tablet computers, laptop computers, etc.). Accordingly, when such batteries run low in capacity to the point that they no longer function to charge the equipment to which they provide power, it may be difficult to precisely and preemptively prevent total shutdown of the equipment. In most cases, the only indication that the battery has run down (or is considered “dead”) is when the equipment no longer functions, but that, in most cases, is too late, particularly for sensitive or active-use equipment (e.g., telecommunications equipment, vehicles, some consumer electronics, some lighting systems, etc.).

Further, there are no current systems known to the inventor that allows a user to track, on a single user interface, a plurality of batteries or to track, on a single user interface, battery characteristics of batteries for each of a plurality of user equipment.

Hence, there is a need for more robust and scalable solutions for implementing wireless capable batteries or wireless capable battery testers, and, in particular embodiments, to methods, systems, apparatus, and computer software for implementing integrated wireless capable batteries/testers or enabling wireless communication between a battery and/or a battery tester and a user device.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIGS. 1A and 1B are schematic diagrams illustrating various systems for implementing or enabling direct or indirect wireless communications between an integrated wireless capable battery/battery tester and one or more user devices, in accordance with various embodiments.

FIGS. 2A and 2B are schematic diagrams illustrating various systems for implementing or enabling direct or indirect wireless communications between an external wireless capable battery tester and one or more user devices, in accordance with various embodiments.

FIGS. 3A-3C are schematic diagrams illustrating various embodiments in which an integrated wireless capable battery/battery tester and/or an external wireless capable battery tester can be utilized within various equipment.

FIGS. 4A-4C are flow diagrams illustrating various methods for implementing or enabling direct or indirect wireless communications between a wireless capable battery and/or a wireless capable battery tester and one or more user devices, in accordance with various embodiments.

FIGS. 5A-5D are schematic diagrams illustrating various examples of user interfaces displayed on various user devices for implementing or enabling direct or indirect wireless communications between a wireless capable battery and/or a wireless capable battery tester and one or more user devices, in accordance with various embodiments.

FIG. 6 is a block diagram illustrating an exemplary computer or system hardware architecture, in accordance with various embodiments.

FIG. 7 is a block diagram illustrating a networked system of computers, computing systems, or system hardware architecture, which can be used in accordance with various embodiments.

### DETAILED DESCRIPTION OF CERTAIN EMBODIMENTS

Overview

Various embodiments provide tools and techniques for implementing wireless capable batteries or wireless capable battery testers, and, in particular embodiments, to methods, systems, apparatus, and computer software for implementing integrated wireless capable batteries/testers or enabling wireless communication between a battery and/or a battery tester and a user device. Herein, “wireless capable battery” might refer to either “a wireless capable battery” or “a wireless capable battery tester,” or both.

In various embodiments, a wireless capable battery or wireless capable battery tester might receive, from one or more sensors of the wireless capable battery tester, one or more measured characteristics (e.g., voltage, current, temperature, location, etc.) of a battery that is installed in equipment (e.g., telecommunications equipment, vehicle, consumer electronics, lighting systems, solar-powered devices, etc.), and might wirelessly send the measured characteristics to one or more user devices. In some cases, the measured characteristics might be sent to a server over a network for analysis prior to sending wirelessly to the user devices. The user devices might receive the measured characteristics, and might display, in a user interface of an app or web portal, the measured characteristics (in some cases, along with recommended courses of action to take, such as replacement, recharge, etc.).

The user interface allows the user to track characteristics of particular batteries (in some cases, a plurality of batteries), as well as providing the user with useful information, including, but not limited to, one or more of remaining capacity, voltage, current, temperature, overall condition, estimated remaining life, location, recommended action to take, current action status, and/or the like, for each battery.

The following detailed description illustrates a few exemplary embodiments in further detail to enable one of skill in the art to practice such embodiments. The described examples are provided for illustrative purposes and are not intended to limit the scope of the invention.

In the following description, for the purposes of explanation, numerous specific details are set forth in order to provide a thorough understanding of the described embodiments. It will be apparent to one skilled in the art, however, that other embodiments of the present invention may be practiced without some of these specific details. In other instances, certain structures and devices are shown in block diagram form. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

Unless otherwise indicated, all numbers used herein to express quantities, dimensions, and so forth used should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components comprising one unit and elements and components that comprise more than one unit, unless specifically stated otherwise.

The tools provided by various embodiments include, without limitation, methods, systems, and/or software products. Merely by way of example, a method might comprise one or more procedures, any or all of which are executed by a computer system. Correspondingly, an embodiment might provide a computer system configured with instructions to perform one or more procedures in accordance with methods provided by various other embodiments. Similarly, a computer program might comprise a set of instructions that are executable by a computer system (and/or a processor therein) to perform such operations. In many cases, such software programs are encoded on physical, tangible, and/or non-transitory computer readable media (such as, to name but a few examples, optical media, magnetic media, and/or the like).

Various embodiments described herein, while embodying (in some cases) software products, computer-performed methods, and/or computer systems, represent tangible, concrete improvements to existing technological areas, including, without limitation, network virtualization technology, network configuration technology, network resource allocation technology, and/or the like. In other aspects, certain embodiments, can improve the functioning of user equipment or systems themselves (e.g., telecommunications equipment, vehicles, consumer and other electronics, lighting systems, solar-powered equipment, battery-powered or battery-backup equipment, etc.), for example, by enabling tracking of characteristics (including, but not limited to, remaining capacity, voltage, current, temperature, overall condition, estimated remaining life, location, recommended action to take, current action status) of batteries that provide power to such equipment or systems thereby obviating sudden shutdown of such equipment or systems due to battery rundown below operational levels, which might damage sensitive components in the equipment or systems and/or might result in loss of data, and/or the like. In particular, to the extent any abstract concepts are present in the various embodiments, those concepts can be implemented as described herein by devices, software, systems, and methods that involve specific novel functionality (e.g., steps or operations), such as enabling wireless tracking of battery characteristics, and/or the like, to name a few examples, that extend beyond mere conventional computer processing operations. These functionalities can produce tangible results outside of the implementing computer system, including, merely by way of example, ability to track the battery capacities, remaining life, etc. of batteries, while preventing sudden shutdown of equipment or systems (particularly, sensitive or active equipment or systems) and any loss of data resulting from such sudden shutdown, which may be observed or measured by customers and/or service providers.

In an aspect, a method might comprise receiving, with a processor of a wireless capable battery tester and from one or more sensors of the wireless capable battery tester, one or more measured characteristics of a battery and wirelessly sending, with the processor via a wireless transceiver of the wireless capable battery tester, the one or more measured characteristics of the battery to one or more user devices.

In some embodiments, the wireless capable battery tester might be integrated within the battery. Alternatively, the wireless capable battery tester might be external to the battery, and at least one of the one or more sensors is coupled to the battery. According to some embodiments, the one or more sensors might include at least one sensor selected from a group consisting of a voltmeter, an ammeter, a thermometer, and a location sensor, and/or the like.

In some cases, wirelessly sending the one or more measured characteristics of the battery to one or more user devices might comprise wirelessly sending, with the processor via the wireless transceiver, the one or more measured characteristics of the battery to one or more user devices using one of Bluetooth protocol, long term evolution (“LTE”) protocol, unlicensed LTE (“LTE-U”) protocol, Wi-Fi protocol, controller area network bus (“CAN bus”) protocol, or 900 MHz band protocol, and/or the like.

According to some embodiments, wirelessly sending the one or more measured characteristics of the battery to one or more user devices might comprise wirelessly sending, with the processor via the wireless transceiver, the one or more measured characteristics of the battery to a server over a network; analyzing, with the server, the one or more measured characteristics of the battery by comparing, with the server, each of the one or more measured characteristics of the battery with corresponding one or more battery characteristics of a battery of the same model or type that are stored in at least one database; and sending, with the server, one or more analyzed characteristics of the battery to the one or more user devices over the network.

Merely by way of example, in some instances, the one or more user devices might comprise at least one of a tablet computer, a smart phone, a mobile phone, a portable gaming device, a laptop computer, or a desktop computer, and/or the like. In some embodiments, the battery might be one of a telecommunications equipment battery within a battery string providing power to telecommunications equipment in a central office or remote cabinet, a battery string providing power to telecommunications equipment in a central office or remote cabinet, a car battery, a boat battery, an aircraft battery, a space station battery, a spacecraft battery, a satellite battery, a consumer electronics battery, a clock battery, a smoke detector battery, a carbon monoxide (“CO”) detector battery, a solar-powered street lamp battery, a solar-powered garden light battery, an electronics backup battery, a marine beacon battery, a seismograph battery, or a weather station battery, and/or the like.

In another aspect, a wireless capable battery tester might comprise one or more sensors, at least one transceiver, at least one processor communicatively coupled to each of the one or more sensors and the at least one transceiver, and a non-transitory computer readable medium communicatively coupled to the at least one processor. The non-transitory computer readable medium might have stored thereon computer software comprising a set of instructions that, when executed by the at least one processor, causes the wireless capable battery tester to: receive, from the one or more sensors, one or more measured characteristics of a battery that the wireless capable battery tester is testing; and wirelessly send, via the at least one transceiver, the one or more measured characteristics of the battery to one or more user devices.

In some embodiments, the wireless capable battery tester might be integrated within the battery. Alternatively, the wireless capable battery tester might be external to the battery, and at least one of the one or more sensors is coupled to the battery. According to some embodiments, the one or more sensors might include at least one sensor selected from a group consisting of a voltmeter, an ammeter, a thermometer, and a location sensor, and/or the like.

In some cases, wirelessly sending the one or more measured characteristics of the battery to one or more user devices might comprise wirelessly sending, with the processor via the wireless transceiver, the one or more measured characteristics of the battery to one or more user devices using one of Bluetooth protocol, long term evolution (“LTE”) protocol, unlicensed LTE (“LTE-U”) protocol, Wi-Fi protocol, controller area network bus (“CAN bus”) protocol, or 900 MHz band protocol, and/or the like.

According to some embodiments, the set of instructions, when executed by the at least one processor, further causes the wireless capable battery tester to wirelessly send, via the wireless transceiver, the one or more measured characteristics of the battery to a server over a network. The server might analyze the one or more measured characteristics of the battery by comparing each of the one or more measured characteristics of the battery with corresponding one or more battery characteristics of a battery of the same model or type that are stored in at least one database, and might send one or more analyzed characteristics of the battery to the one or more user devices over the network.

Merely by way of example, in some instances, the one or more user devices might comprise at least one of a tablet computer, a smart phone, a mobile phone, a portable gaming device, a laptop computer, or a desktop computer, and/or the like. In some embodiments, the battery might be one of a telecommunications equipment battery within a battery string providing power to telecommunications equipment in a central office or remote cabinet, a battery string providing power to telecommunications equipment in a central office or remote cabinet, a car battery, a boat battery, an aircraft battery, a space station battery, a spacecraft battery, a satellite battery, a consumer electronics battery, a clock battery, a smoke detector battery, a carbon monoxide (“CO”) detector battery, a solar-powered street lamp battery, a solar-powered garden light battery, an electronics backup battery, a marine beacon battery, a seismograph battery, or a weather station battery, and/or the like.

In yet another aspect, a method might comprise wirelessly receiving, with a processor of a user device via a wireless transceiver of the user device, one or more characteristics of a battery as measured by a wireless capable battery tester and displaying, with the processor and on a display screen of the user device, a user interface, the user interface presenting the one or more characteristics of the battery.

In some embodiments, the one or more characteristics of the battery might include at least one of voltage, amperage, or temperature of the battery. According to some embodiments, the method might further comprise calculating, with the processor, at least one of a current percentage of remaining battery charge, an estimated remaining life, or a current overall condition of the battery, based at least in part on the one or more characteristics of the battery, and displaying, via the user interface, the calculated at least one of the current percentage of remaining battery charge, the estimated remaining life, or the current overall condition of the battery.

In some cases, the method might further comprise at least one of, based on the calculated current percentage of remaining battery charge of the battery, displaying a notification indicating to recharge the battery, or, based on the calculated estimated remaining life of the battery, displaying a notification indicating to replace the battery. According to some embodiments, the one or more characteristics might further comprise a location of the battery, and the method might further comprise displaying, via the user interface, the location of the battery.

Merely by way of example, in some embodiments, the method might further comprise wirelessly receiving, with the processor via the wireless transceiver of the user device, one or more characteristics of each of a plurality of second batteries as measured by one or more wireless capable battery testers and displaying, with the processor via the user interface, the one or more characteristics of each of the plurality of second batteries.

Various modifications and additions can be made to the embodiments discussed without departing from the scope of the invention. For example, while the embodiments described above refer to particular features, the scope of this invention also includes embodiments having different combination of features and embodiments that do not include all of the above described features.

### Specific Exemplary Embodiments

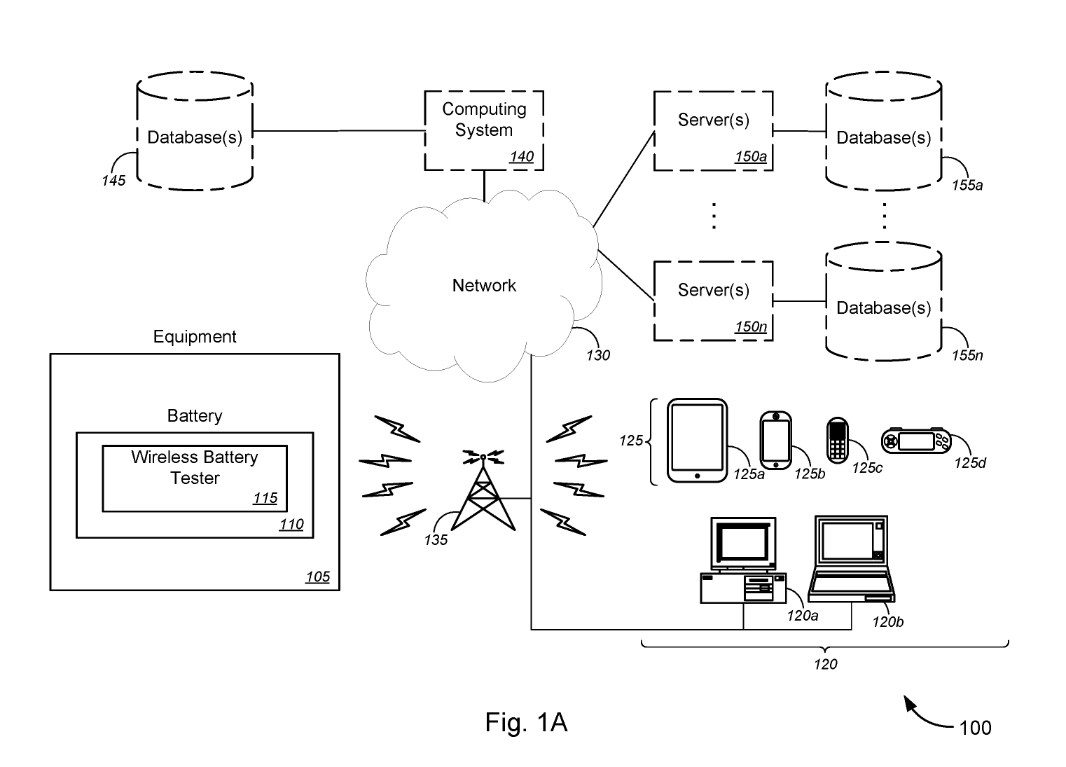

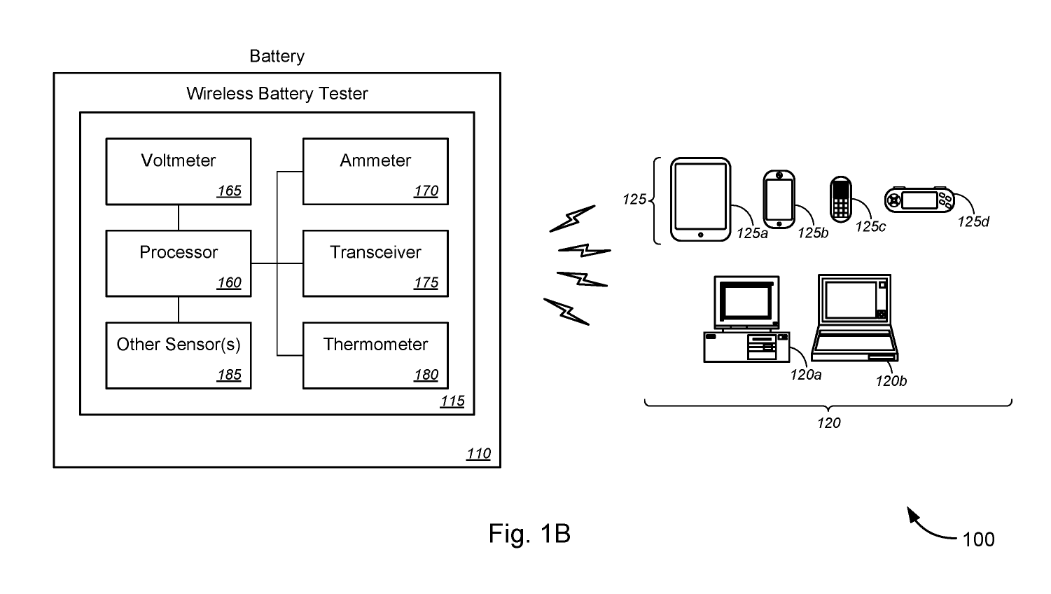

We now turn to the embodiments as illustrated by the drawings. FIGS. 1-7 illustrate some of the features of the method, system, and apparatus for implementing wireless capable batteries or wireless capable battery testers, and, in particular embodiments, to methods, systems, apparatus, and computer software for implementing integrated wireless capable batteries/testers or enabling wireless communication between a battery and/or a battery tester and a user device, as referred to above. The methods, systems, and apparatuses illustrated by FIGS. 1-7 refer to examples of different embodiments that include various components and steps, which can be considered alternatives or which can be used in conjunction with one another in the various embodiments. The description of the illustrated methods, systems, and apparatuses shown in FIGS. 1-7 is provided for purposes of illustration and should not be considered to limit the scope of the different embodiments.

With reference to the figures, FIGS. 1A and 1B (collectively, “FIG. 1”) are schematic diagrams illustrating various systems 100 for implementing or enabling direct or indirect wireless communications between an integrated wireless capable battery/battery tester and one or more user devices, in accordance with various embodiments.

In the embodiment of FIG. 1A, system 100 might comprise at least one equipment 105, which might each include, without limitation, one of telecommunications equipment, a vehicle, an electronics device, a solar-powered and/or battery-powered device, or other battery-powered or battery-backup devices, and/or the like. In some cases, the telecommunications equipment might include, but is not limited to, at least one of telecommunications equipment housed within equipment racks in a telecommunications office (e.g., a central office, a remote cabinet, etc.), telecommunications equipment located at a customer premises (e.g., residential premises, business premises, or industrial sites, etc.), telecommunications equipment located in or on the ground within the last mile of customer premises, and/or the like. In some instances, the vehicle might include, without limitation, one of a minivan, a van, a pickup truck, a semi-tractor trailer truck, an SUV, a motorcycle, a scooter, a battery-enhanced or battery-powered bicycle, a battery-enhanced or battery-powered wheelchair, a segway or similar type of personal conveyance, a boat, an aircraft, a space station, a spacecraft, and/or the like. The electronics device, in some cases, might include, but is not limited to, one of a clock, a smoke detector, a carbon monoxide (“CO”) detector, a speaker, a flashlight, a radio, a remote control device, and/or the like.

System 100 might further comprise a battery 110 that is disposed within and that powers the equipment 105. The battery 110 might include an integrated wireless or wireless capable battery tester 115 that measures one or more characteristics of the battery, and that wirelessly sends the one or more measured characteristics of the battery (including, but not limited to, voltage, amperage, and/or temperature of the battery) to one or more user devices 120, which might include one or more mobile user device 125, via network 130, and in some cases, via one or more telecommunications relay systems 135. The one or more telecommunications relay systems 135 might include, without limitation, one or more wireless network interfaces (e.g., wireless modems, wireless access points, and the like), one or more towers, one or more satellites, and/or the like.

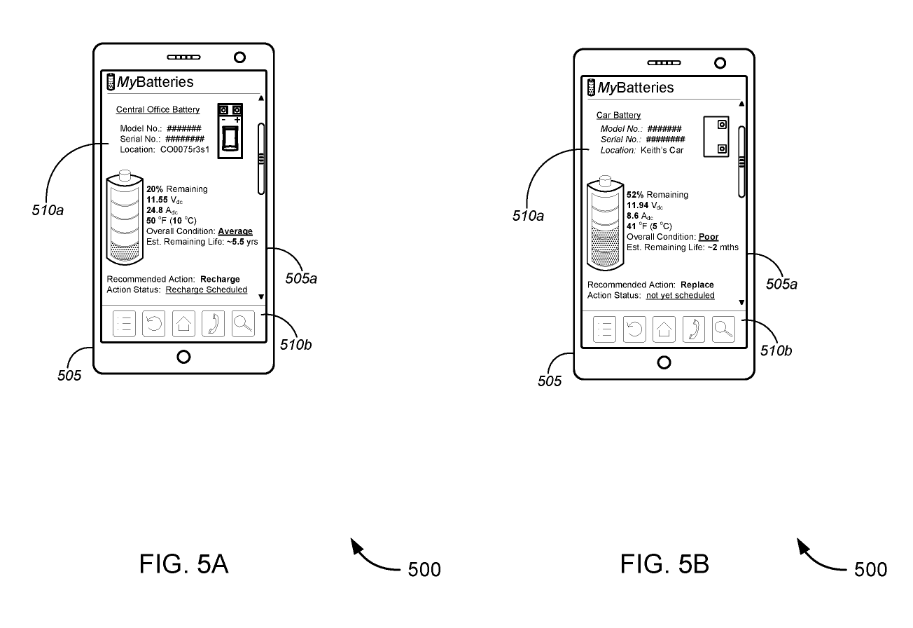

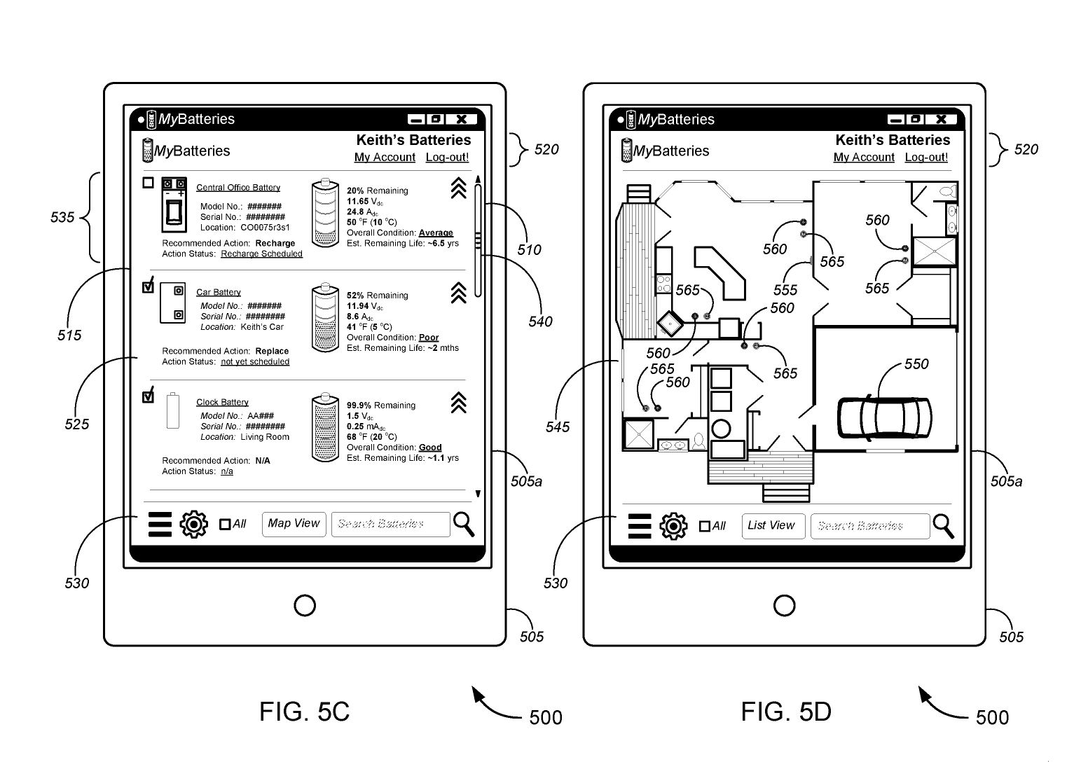

The one or more user devices 120 might include, but are not limited to, a desktop computer 120a, a laptop computer 120b, and/or the like, while the one or more mobile user devices 125 might include, without limitation, a tablet computer 125a, a smart phone 125b, a mobile phone 125c, a portable gaming device 125d, and/or the like. In various embodiments, as shown and described below with respect to FIGS. 5A-5D, the one or more user devices 120 might wirelessly receive the one or more characteristics of the battery 110 as measured by the wireless capable battery tester 115, and might display on a display screen of the user device 120, via a user interface, the one or more characteristics of the battery 110.

In some embodiments, system 100 might further comprise computing system or server 140 that communicatively couples to network 130. System 100 might also comprise one or more databases 145 that is in communication with server 140. In operation, the wireless battery tester 115 might send, via network 130 (and, in some cases, via the one or more telecommunications relay systems 135), the one or more measured characteristics of the battery 110 to the server 140, which might analyze the one or more measured characteristics of the battery by comparing each of the one or more measured characteristics of the battery with corresponding one or more battery characteristics of a battery of the same model or type that are stored in database(s) 145 or by communicating with one or more of servers 150a-150n (which are associated with at least one of manufacturers of the battery 110, trade groups that perform standardized performance/characteristic testing of batteries like battery 110, and/or standards groups or organizations that perform standardized performance/characteristic testing of batteries like battery 110) to compare each of the one or more measured characteristics of the battery with corresponding one or more battery characteristics of a battery of the same model or type that are stored in one or more databases 155a-155n that are respectively associated with the one or more servers 150a-150n.

In FIG. 1, in general, the lines connecting components of the system can represent either wired connection between two or more components, wireless communications between the two or more components, or both. The lightning bolt symbols, however, represent and highlight wireless communications capability between the two or more components, and the combination of the lines and the lightning bolts represents that one or both of these two types of communications (wired and/or wireless) may be implemented as depicted, or the like. Also in FIG. 1, the dash/long-dash lines outlining component blocks (e.g., computing system 140, servers 150a-150n, and databases 145 and 155a-155n) represent optional or alternative components of system 100.

Although FIG. 1A shows wireless communication between the integrated wireless capable battery 110/wireless capable battery tester 115 and the one or more user devices via network 130 (and, in some cases, via the one or more telecommunications relay systems 135), the various embodiments are not so limited, and the integrated wireless capable battery 110/wireless capable battery tester 115 can directly wirelessly communicate with the one or more user devices 120, as shown in the embodiment of FIG. 1B. In the embodiment of FIG. 1B, wireless battery tester 115, which is integrated with or within battery 110, might comprise at least one of a processor 160, a voltmeter 165, an ammeter 170, a wireless transceiver 175, a thermometer 180, one or more other sensors 185, and/or the like. The processor 160 (which might be a microprocessor, micro-circuitry, or the like) might directly send, via wireless transceiver 175, the one or more measured characteristics of the battery 110 to the one or more user devices 120. In some cases, the sensors of the wireless battery tester 115 might comprise one of voltmeter 165, ammeter 170, thermometer 180, or other sensors 185, and/or the like. Alternatively, the sensors of the wireless battery tester 115 might comprise a combination of two or more of voltmeter 165, ammeter 170, thermometer 180, or other sensors 185, and/or the like. In some embodiments, the other sensors 185 might comprise a location sensor, which might be based on a navigation system, including global positioning system (“GPS”) or equivalent system, and/or the like, based on a position triangulation system, and/or the like.

In FIG. 1, wirelessly sending the one or more measured characteristics of the battery 110 (either directly or indirectly via network 130 and/or telecommunications relay system 135) to the one or more user devices 120 might comprise wirelessly sending, via the wireless transceiver 175, the one or more measured characteristics of the battery 110 to the one or more user devices 120 using one of Bluetooth protocol, long term evolution (“LTE”) protocol, unlicensed LTE (“LTE-U”) protocol, Wi-Fi protocol, controller area network bus (“CAN bus”) protocol, or 900 MHz band protocol, and/or the like. In some embodiments, the one or more measured characteristics of the battery 100 might be at least one of sent on a periodic basis, sent during high performance operation of the equipment (i.e., high battery draw), sent during low or no performance operation of the equipment (i.e., low or no battery draw (e.g., during idle periods or the like)), and/or sent upon request or update by the user or user interface on the user device.

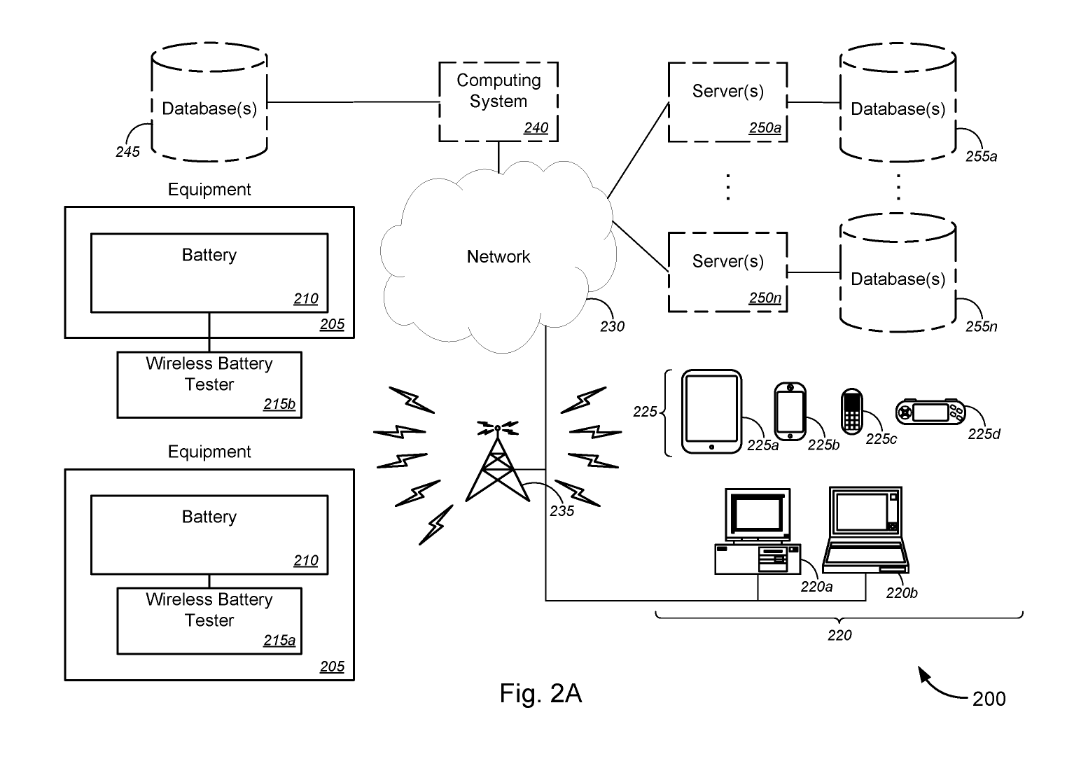

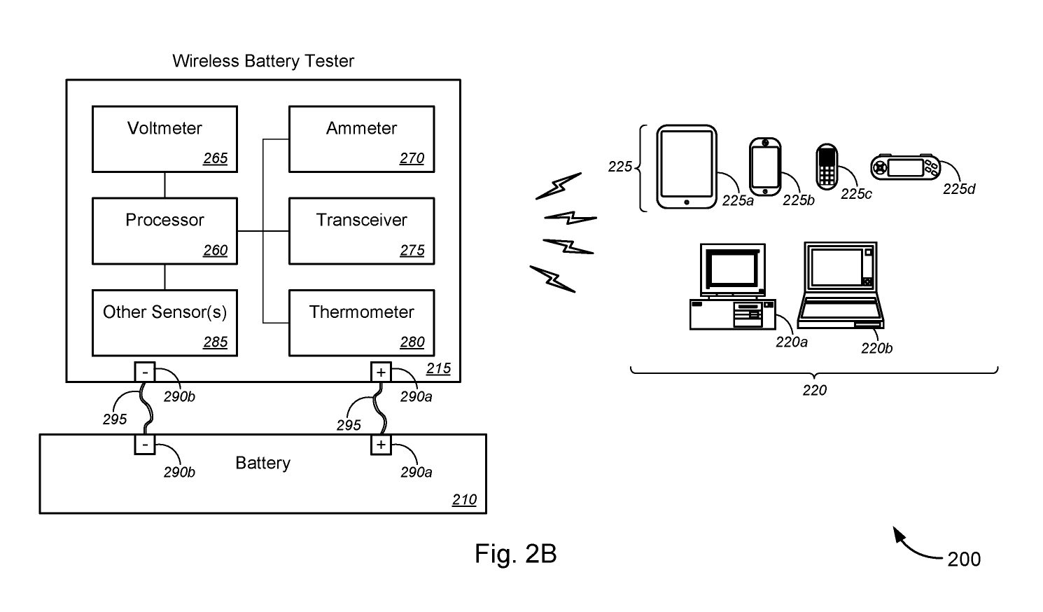

FIGS. 2A and 2B (collectively, “FIG. 2”) are schematic diagrams illustrating various systems 200 for implementing or enabling direct or indirect wireless communications between an external wireless capable battery tester and one or more user devices, in accordance with various embodiments. In FIG. 2, equipment 205, battery 210, wireless battery tester 215, user devices 220, mobile user devices 225, network 230, telecommunications relay system 235, computing system or server 240, database(s) 245, one or more servers 250a-250n, databases 255a-255n, processor 260, voltmeter 265, ammeter 270, transceiver 275, thermometer 280, and other sensors 285 of system 200 correspond to equipment 105, battery 110, wireless battery tester 115, user devices 120, mobile user devices 125, network 130, telecommunications relay system 135, computing system or server 140, database(s) 145, one or more servers 150a-150n, databases 155a-155n, processor 160, voltmeter 165, ammeter 170, transceiver 175, thermometer 180, and other sensors 185 of system 100 of FIG. 1, except that wireless battery tester 215 is external to (while at least one or more sensors are coupled to) the battery 210, either housed in equipment 205 together with battery 210 (as depicted by wireless battery tester 215a of FIG. 2A) or external to both equipment 205 and battery 210 (as depicted by wireless battery tester 215b of FIG. 2B). These components of system 200 are otherwise similar to, or the same as, the corresponding components of system 100, and the descriptions of these components apply similarly.

With reference to FIG. 2B, in some embodiments, the positive terminals 290a on the battery 210 and on the wireless battery tester 215 might be communicatively coupled via wires, cables, probes, contacts, or leads 295, while negative terminals 290b on the battery 210 and on the wireless battery tester 215 might be communicatively coupled via wires, cables, or leads 295, to measure at least one of voltage or amperage. Temperature, location, and other characteristics might not require wired connection to the battery for measurement (although a thermocouple might be used to measure temperature of the battery by connecting to the battery). Other measurements of temperature, location, and the like might, in some cases, take measurements in a location proximate, adjacent, or near the battery 110, without direct connection to the battery 110. For example, a laser or infrared thermometer might accurately measure temperature of a portion or an entirety of battery 110 without making direct physical contact with the battery 110.

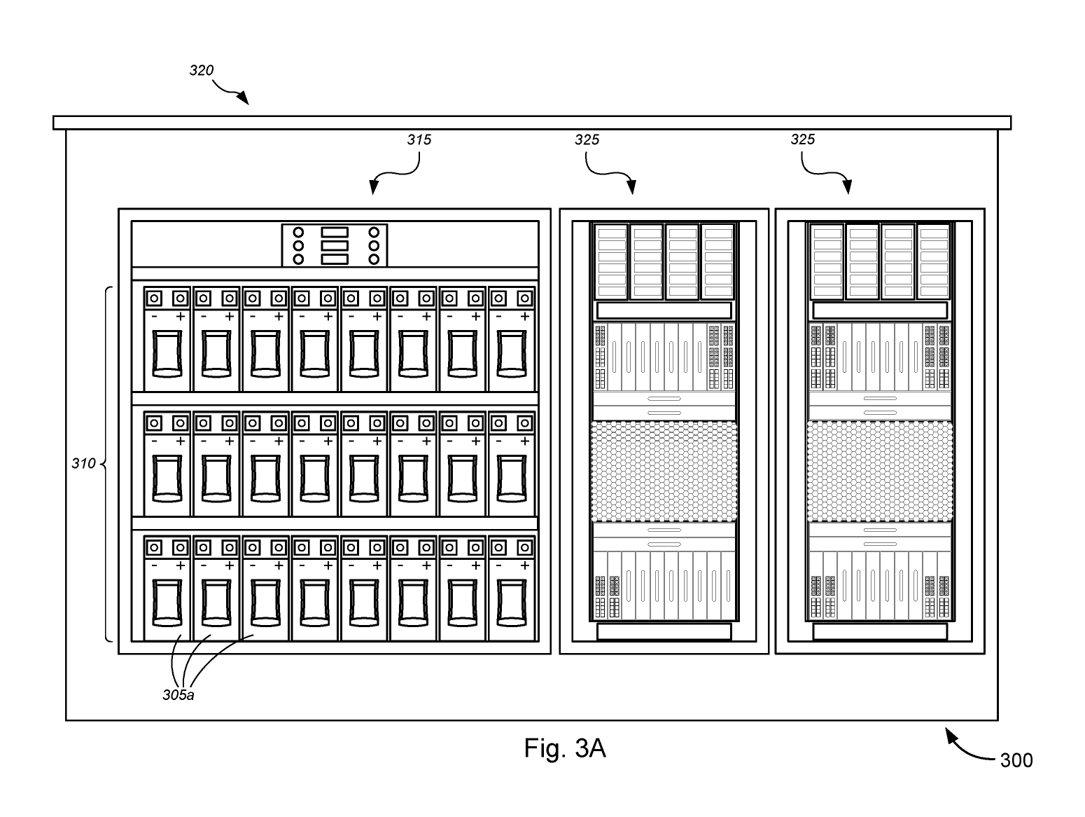

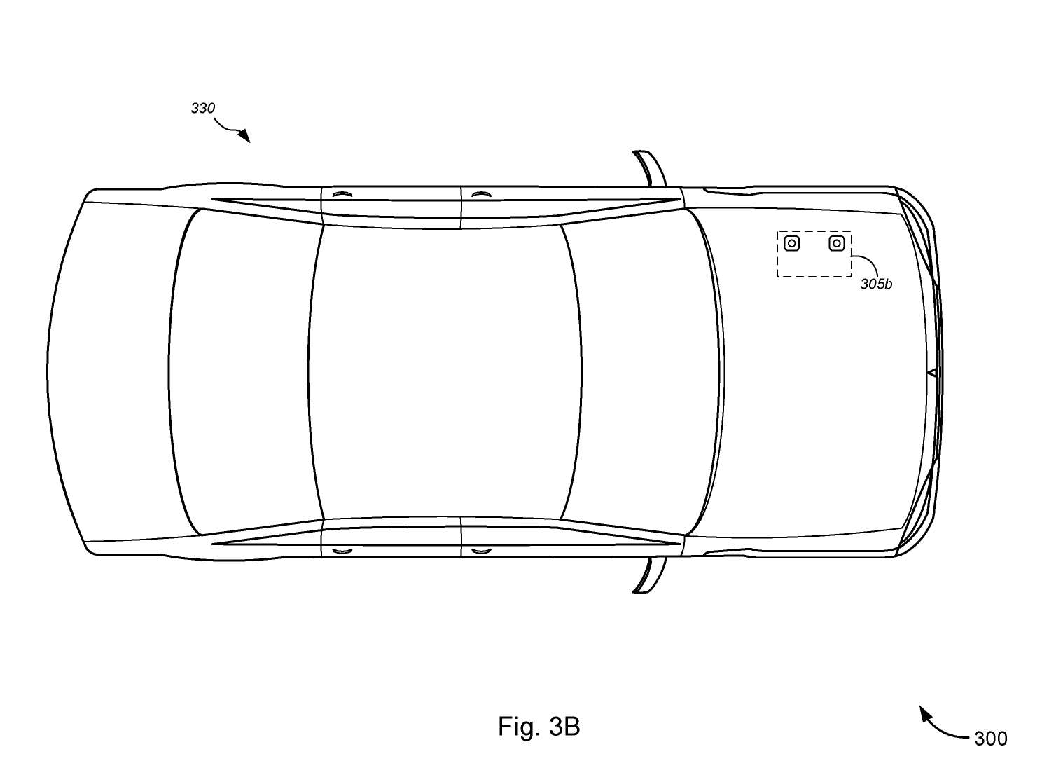

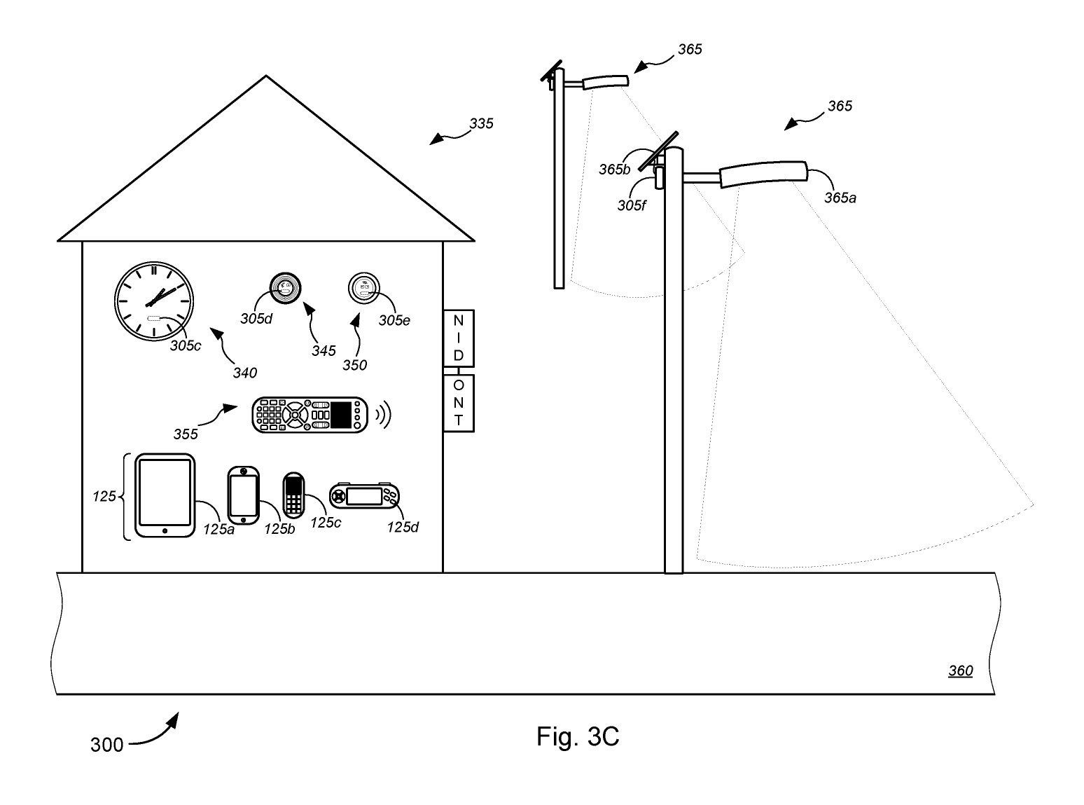

FIGS. 3A-3C (collectively, “FIG. 3”) are schematic diagrams illustrating various embodiments 300 in which an integrated wireless capable battery/battery tester and/or an external wireless capable battery tester can be utilized within various equipment. For example, FIG. 3A depicts a plurality of telecommunications batteries 305a that are connected in a battery string 310 within a battery rack 315 that is located within a telecommunications office (e.g., a central office, a remote cabinet, and/or the like), which might house one or more telecommunications equipment racks 325 having one or more telecommunications equipment components housed therein. The telecommunications batteries 305a—which might be either an integrated wireless capable battery/tester (as shown and described above with respect to FIG. 1) or an external wireless capable battery tester and battery (as shown and described above with respect to FIG. 2)—serve to provide primary or backup power to the one or more telecommunications equipment components that are housed in the telecommunications equipment racks 325.

According to some embodiments, an integrated wireless capable battery/battery tester and/or an external wireless capable battery tester might be used for valve regulated lead acid batteries (e.g., 12V 170 Ah or 190 Ah front terminal battery strings, or the like) or Ni-Cad batteries (e.g., Ni-Cad 150 Ah cell battery strings, or the like), and/or the like that are used in remote cabinets, or used for lead acid batteries or the like that might be used in central offices. In some cases, some telecommunications batteries might have lengths ranging between ˜5.59 inches (or ˜14.20 cm) or shorter and ˜16.60 inches (or ˜42.16 cm) or longer, widths ranging between ˜10.44 inches (or ˜26.52 cm) or shorter and ˜17.25 inches (or ˜43.82 cm) or wider, and heights of between ˜18.25 inches (or ˜46.36 cm) or shorter and ˜28.90 inches (or ˜73.41 cm) or taller. These dimensions in some cases might be indicative of the limited space in which each battery might reside, and thus any integrated battery/battery tester must (in such cases) be designed to fit within such size limitations. In other cases, placement sizes might allow for expansion of the battery in at least one of the three dimensions to accommodate the integrated battery/battery tester or to accommodate an external battery tester for each battery.

In the non-limiting example of FIG. 3B, a car battery 305b—which might be either an integrated wireless capable battery/tester (as shown and described above with respect to FIG. 1) or an external wireless capable battery tester and battery (as shown and described above with respect to FIG. 2)—might serve to provide power to a car 330. Although a car is shown in FIG. 3B, the various embodiments are not so limited, the wireless capable battery and/or wireless capable battery tester (as described above with respect to FIGS. 1 and 2) might be used in or on any vehicle or moving object that requires use of a battery—including, without limitation, a minivan, a van, a pickup truck, a semi-tractor trailer truck, an SUV, a motorcycle, a scooter, a battery-enhanced or battery-powered bicycle, a battery-enhanced or battery-powered wheelchair, a segway or similar type of personal conveyance, a boat, an aircraft, a space station, a spacecraft, a satellite, and/or the like.

With reference to FIG. 3C, system 300 might comprise a clock battery 305c, a smoke detector battery 305d, and a carbon monoxide (“CO”) detector battery 305e (collectively, “consumer electronics batteries”)—each of which might be either an integrated wireless capable battery/tester (as shown and described above with respect to FIG. 1) or an external wireless capable battery tester and battery (as shown and described above with respect to FIG. 2)—that are located within a customer premises 335 and are housed within, and power, a clock 340, a smoke detector 345, and a CO detector, respectively. In some cases, system 300 might further comprise a remote control device 355 for remotely controlling consumer electronics (e.g., televisions (“TVs”), set-top boxes (“STBs”), gaming consoles, light fixtures, fans, shades, curtains, blinds, sunroofs, automated windows, automated doors, etc.). The remote control device might similarly utilize one or more batteries, each of which might be either an integrated wireless capable battery/tester (as shown and described above with respect to FIG. 1) or an external wireless capable battery tester and battery (as shown and described above with respect to FIG. 2).

In some embodiments, although some mobile devices have incorporated therein battery capacity measurement devices and/or the like, mobile devices, including, but not limited to, a tablet computer 125a, a smart phone 125b, a mobile phone 125c, and a portable gaming device 125d, and/or the like might each utilize a battery that is either an integrated wireless capable battery/tester (as shown and described above with respect to FIG. 1) or an external wireless capable battery tester and battery (as shown and described above with respect to FIG. 2). Alternatively, a user interface on one or more user devices might allow the user to collect or receive battery capacity measurements or the like from mobile devices that already have built-in battery capacity measurement devices. In this manner, any and all user devices or equipment that utilize a battery as a power source can be tracked in a single app or user interface in terms of remaining battery levels or capacity, remaining battery life, and/or the like (in a manner as shown, at least in part, with respect to the embodiments of FIGS. 5C and 5D below. In some embodiments herein, the mobile devices 125 might also be classified as or referred to as consumer electronics for the purposes of facilitating description of the various embodiments.

Although consumer electronics are shown as including a clock 340, a smoke detector 345, a CO detector 350, and one or more mobile devices 125, the various embodiments are not so limited and consumer electronics batteries (as described above) may be used in other types of consumer electronics, household electronics, residential electronics, business electronics, industrial electronics, and/or the like, as appropriate and/or as desired.

Also as shown in the embodiment of FIG. 3C, system 300 might further comprise, on ground surface 360, one or more solar-powered street lamps 365 (also referred to as “solar-powered street lights,” “solar-powered lamp posts,” and/or the like), which might comprise a light or lighting fixture 365a, a solar panel 365b, and a battery 305f. The light fixture 365a might comprise one of an incandescent light bulb(s), a fluorescent light bulb(s), a compact fluorescent light (“CFL”) bulb(s), a light emitting diode (“LED”) bulb(s), a halogen lamp(s), and/or the like. The solar panel 365b may be any solar panel or any suitable dimension that are mounted or mountable on the street lamp 365. In some cases, the solar panel 365b may be fixably mounted at a prescribed angle to optimize solar light collection during the day throughout the year, while, in other cases, the solar panel 365b might be mounted on a movable mount that automatically adjusts the angle and orientation of the solar panel 365b to optimize solar light collection either based on a preset algorithm or programming or based on a determination as to optimal angle and orientation that is based on the actual solar light collected. The battery 305f may be housed in a water and weather—proof container that is affixed to the street lamp 365, and may be a battery that is either an integrated wireless capable battery/tester (as shown and described above with respect to FIG. 1) or an external wireless capable battery tester and battery (as shown and described above with respect to FIG. 2).

In a similar manner as the solar-powered street lamps 365, any other lighting appliance—including, but not limited to, battery-powered garden lights, solar-powered garden lights, battery-powered patio lights, solar-powered patio lights, battery-powered security lights, solar-powered security lights, battery-powered cabinet lights, battery-powered closet lights, battery-powered attic lights, battery-powered flash lights, battery-powered or solar-powered indoor lamps, and/or the like—may utilize an integrated wireless capable battery/tester (as shown and described above with respect to FIG. 1) or an external wireless capable battery tester and battery (as shown and described above with respect to FIG. 2), as appropriate or as desired.

Although not shown or described in the embodiments of FIG. 3, other equipment (aside from those already mentioned above) that might benefit from use of an integrated wireless capable battery/tester (as shown and described above with respect to FIG. 1) or an external wireless capable battery tester and battery (as shown and described above with respect to FIG. 2) might include, without limitation, a standalone electronics backup device, a power-bar type electronics backup device with battery, a marine beacon, a seismograph (particularly, a remotely disposed or mounted seismograph), a weather station (particularly, remotely disposed or mounted weather station), and/or the like.

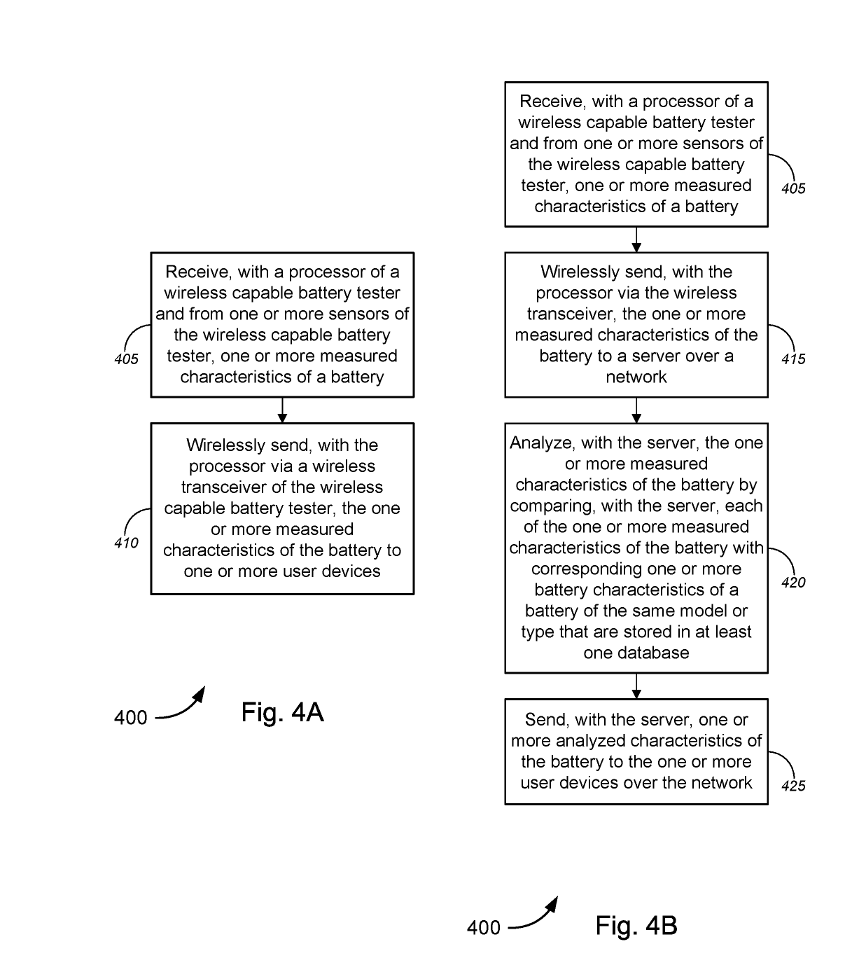

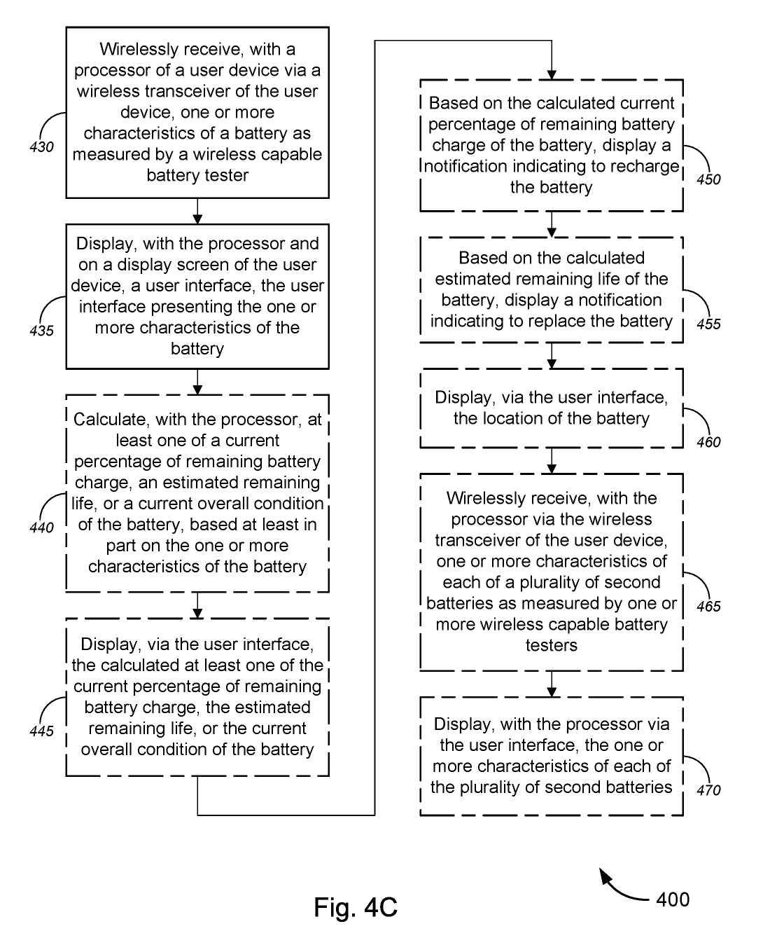

FIGS. 4A-4C (collectively, “FIG. 4”) are flow diagrams illustrating various methods 400 for implementing or enabling direct or indirect wireless communications between a wireless capable battery and/or a wireless capable battery tester and one or more user devices, in accordance with various embodiments. FIGS. 4A and 4B depict processes performed by a wireless capable battery and/or a wireless capable battery tester that is in direct communication with one or more user devices (FIG. 4A) or that is indirectly in communication with the one or more user devices via a server computer (FIG. 4B), while FIG. 4C depicts processes performed by a user device in communication with a wireless capable battery and/or a wireless capable battery tester.

While the techniques and procedures are depicted and/or described in a certain order for purposes of illustration, it should be appreciated that certain procedures may be reordered and/or omitted within the scope of various embodiments. Moreover, while the method illustrated by FIG. 4 can be implemented by or with (and, in some cases, are described below with respect to) the systems 100, 200, 300, and 500 of FIGS. 1, 2, 3, and 5, respectively (or components thereof), such methods may also be implemented using any suitable hardware (or software) implementation. Similarly, while each of the systems 100, 200, 300, and 500 of FIGS. 1, 2, 3, and 5, respectively (or components thereof), can operate according to the method illustrated by FIG. 4 (e.g., by executing instructions embodied on a computer readable medium), the systems 100, 200, 300, and 500 of FIGS. 1, 2, 3, and 5 can each also operate according to other modes of operation and/or perform other suitable procedures.

Turning to FIG. 4A, method 400 might comprise receiving, with a processor of a wireless capable battery tester and from one or more sensors of the wireless capable battery tester, one or more measured characteristics of a battery (block 405). In some embodiments, the wireless capable battery tester might be integrated within the battery. Alternatively, the wireless capable battery tester might be external to the battery, and at least one of the one or more sensors is coupled to the battery. According to some embodiments, the one or more sensors might include at least one sensor selected from a group consisting of a voltmeter, an ammeter, a thermometer, and a location sensor, and/or the like.

Merely by way of example, in some embodiments, the battery might be one of a telecommunications equipment battery within a battery string providing power to telecommunications equipment in a central office or remote cabinet, a battery string providing power to telecommunications equipment in a central office or remote cabinet, a car battery, a boat battery, an aircraft battery, a space station battery, a spacecraft battery, a satellite battery, a consumer electronics battery, a clock battery, a smoke detector battery, a carbon monoxide (“CO”) detector battery, a solar-powered street lamp battery, a solar-powered garden light battery, an electronics backup battery, a marine beacon battery, a seismograph battery, or a weather station battery, and/or the like. In some cases, the battery might be one of an alkaline battery, a nickel metal hydride (“NiMH”) battery, a lithium ion battery, a lead-acid battery, a nickel cadmium (“NiCad”), a polymer-based battery, a rechargeable battery, and/or the like.

At block 410, method 400 might comprise wirelessly sending, with the processor via a wireless transceiver of the wireless capable battery tester, the one or more measured characteristics of the battery (directly) to one or more user devices. In some instances, the one or more user devices comprises at least one of a tablet computer, a smart phone, a mobile phone, a portable gaming device, a laptop computer, or a desktop computer, and/or the like. According to some embodiments, wirelessly sending the one or more measured characteristics of the battery to one or more user devices might comprise wirelessly sending, with the processor via the wireless transceiver, the one or more measured characteristics of the battery to one or more user devices using one of Bluetooth protocol, long term evolution (“LTE”) protocol, unlicensed LTE (“LTE-U”) protocol, Wi-Fi protocol, controller area network bus (“CAN bus”) protocol, or 900 MHz band protocol, and/or the like.

With reference to FIG. 4B, method 400 might comprise receiving, with a processor of a wireless capable battery tester and from one or more sensors of the wireless capable battery tester, one or more measured characteristics of a battery (block 405; same as in the embodiment of FIG. 4A). Instead of the direct communication between the wireless capable battery tester and the one or more user devices (as at block 410 of FIG. 4A), method 400 of FIG. 4B might comprise wirelessly sending, with the processor via the wireless transceiver, the one or more measured characteristics of the battery to a server over a network (block 415), analyzing, with the server, the one or more measured characteristics of the battery by comparing, with the server, each of the one or more measured characteristics of the battery with corresponding one or more battery characteristics of a battery of the same model or type that are stored in at least one database (block 420), and sending, with the server, one or more analyzed characteristics of the battery to the one or more user devices over the network (block 425).

In the embodiment of FIG. 4C, method 400 might comprise wirelessly receiving, with a processor of a user device via a wireless transceiver of the user device, one or more characteristics of a battery as measured by a wireless capable battery tester (block 430) and displaying, with the processor and on a display screen of the user device, a user interface, the user interface presenting the one or more characteristics of the battery (block 435). In some cases, the one or more characteristics of the battery might include, without limitation, at least one of voltage, amperage, temperature, and/or the like, of the battery. FIGS. 5A-5C depict some non-limiting examples of displaying characteristics of batteries in a user interface on a user device.

In some embodiments, method 400 might further comprise, at optional block 440, calculating, with the processor, at least one of a current percentage of remaining battery charge, an estimated remaining life, or a current overall condition of the battery, based at least in part on the one or more characteristics of the battery, and, at optional block 445, displaying, via the user interface, the calculated at least one of the current percentage of remaining battery charge, the estimated remaining life, or the current overall condition of the battery. FIGS. 5A-5C depict some non-limiting examples of displaying estimated remaining life of batteries in a user interface on a user device.

According to some embodiments, method 400 might further comprise at least one of, based on the calculated current percentage of remaining battery charge of the battery, displaying a notification indicating to recharge the battery (optional block 450) (as shown in the non-limiting example of FIG. 5A) or, based on the calculated estimated remaining life of the battery, displaying a notification indicating to replace the battery (optional block 455) (as shown in the non-limiting example of FIG. 5B).

In some cases, the one or more characteristics might further comprise a location of the battery, and method 400 might further comprise, at optional block 460, displaying, via the user interface, the location of the battery. FIGS. 5A-5C depict some non-limiting examples of displaying a text of the location of batteries in a user interface on a user device, while FIG. 5D depicts a non-limiting example of displaying a map-based location of batteries in a user interface on a user device.

In some embodiments, method 400 might further comprise wirelessly receiving, with the processor via the wireless transceiver of the user device, one or more characteristics of each of a plurality of second batteries as measured by one or more wireless capable battery testers (optional block 465) and displaying, with the processor via the user interface, the one or more characteristics of each of the plurality of second batteries (optional block 470). FIGS. 5C and 5D depict some non-limiting examples of displaying a plurality of batteries in a user interface on a user device.

FIGS. 5A-5D (collectively, “FIG. 5”) are schematic diagrams illustrating various examples of user interfaces displayed on various user devices 500 for implementing or enabling direct or indirect wireless communications between a wireless capable battery and/or a wireless capable battery tester and one or more user devices, in accordance with various embodiments.

In the embodiments of FIGS. 5A and 5B, user device 500 (in this example, a smart phone, although not limited to such) might comprise a housing 505 and a display screen 505a (which, in most cases, is a touchscreen display). The display screen 505a might display or present a first display panel, window, or segment 510a and a second display panel, window, or segment 510b. In some embodiments, the first display panel, window, or segment 510a might display or present a user interface (in some cases, a graphical user interface (“GUI”) or the like) that presents information about or characteristics of a battery, while the second display panel, window, or segment 510b might display or present icons or buttons for actuating functionalities of the phone (including, but not limited to, one or more of menu functionality, back functionality, navigate to home functionality, call functionality, search functionality, and/or the like). In some cases, the user interface might be a user interface for a software application (“app”), a web portal, and/or the like.

As shown in the example of FIG. 5A, for instance, the characteristics of the battery (in this example, a central office battery (such as shown and described above with respect to FIG. 3A) might include, without limitation, a model number of the battery, a serial number of the battery, a location of the battery (which might include information regarding which central office location, which rack number, which slot number, and/or the like), remaining capacity of the battery (in this case, 20%), voltage (in this case, 11.55 V_{dc}), amperage or current draw (in this case, 24.8 A_{dc}), operating or current temperature (in this case, ˜50° F. or ˜10° C.), overall condition (in this case, average), estimated remaining life (in this case, ˜5.5 years), recommended action to take (in this case, to recharge the battery), and action status (in this case, that a recharge has been scheduled for this particular battery), and/or the like.

With reference to the example of FIG. 5B, the characteristics of the battery (in this example, a car battery (such as shown and described above with respect to FIG. 3B) might include, without limitation, a model number of the battery, a serial number of the battery, a location of the battery (which might include which car the battery is currently mounted in, the location of the car, and/or the like), remaining capacity of the battery (in this case, 52%), voltage (in this case, 11.94 V_{dc}), amperage or current draw (in this case, 8.6 A_{dc}), operating or current temperature (in this case, ˜41° F. or ˜5° C.), overall condition (in this case, poor), estimated remaining life (in this case, ˜2 months), recommended action to take (in this case, to replace the battery), and action status (in this case, that a replacement service has been yet been scheduled for this particular battery), and/or the like. In some cases, although not shown, the user interface might present information (e.g., in the form of links, names, addresses, or description, and the like of on-line or physical stores that carry or sell the particular battery).

In the embodiments of FIGS. 5C and 5D, user device 500 (in this example, a tablet computer, although not limited to such) might comprise a housing 505 and a display screen 505a (which, in most cases, is a touchscreen display). The display screen 505a might display or present a panel or window 515, which might be divided into segments, including, but not limited to, a header 520, a first display sub-panel, sub-window, or segment 525, and a second display sub-panel, sub-window, or segment 530. In some embodiments, the header might present an icon or logo and/or name of the app, program, or service (in this case, “MyBatteries”), as well as an indication of the user (in this case, “Keith's Batteries” indicating that the user is “Keith”), my account button or link (that allows the user to select preferences for the account, to add, update, or delete account settings, and/or the like), and a log-out link or button. According to some embodiments, the first display sub-panel, sub-window, or segment 525 might present a list view of a plurality of batteries that the user has associated with his or her account (in this case, a central office battery (for work), a car battery (for transportation), and a clock battery (for home), and/or the like). Each battery might be displayed as an entry item 535, and the first display sub-panel, sub-window, or segment 525 might include a slider bar that allows the user to scroll up or down to view other batteries that are associated with his or her account, but are listed beyond the current view of the screen. Although not shown, the upward-pointing chevron arrows might allow the user to minimize the view of selected entry items 535, with downward-point chevron arrows (not shown) allowing the user to subsequently maximize such minimized views of the entry items 535. The information or characteristics of the batteries displayed in the first display sub-panel, sub-window, or segment 525 might be similar, if not identical, to those displayed in the first display panel, window, or segment 510a of the user interface of FIG. 5A or 5B, except that format and arrangement might be different.

In some cases, second display sub-panel, sub-window, or segment 530 might present icons or buttons that provide other functionalities of the app or program, including, but not limited to, menu functionality, settings functionality, select/de-select all functionality, map view functionality, search batteries functionality, and/or the like.

With reference to FIG. 5D, when the “map view” icon or button is depressed or actuated, a map might be displayed or presented in a third display sub-panel, sub-window, or segment 545 (that replaces the first display sub-panel, sub-window, or segment 525). In the non-limiting example of FIG. 5D, the map might include a floorplan of the user's home (or customer premises), with icons representing equipment in which the wireless capable batteries/wireless capable battery testers are installed. Such equipment, for instance, might include, without limitation, a car 550 (in this case, “Keith's car”) that is located in the garage, a clock 555 that is located in the living room, and smoke detectors 560 and CO detectors 565 that are located near the entryway, in the living room, in the kitchen, in the master bedroom, and in the second bedroom, and/or the like. Although not shown, other equipment that might have installed therein wireless capable batteries/wireless capable battery testers might include, but are not limited to, one or more remote control devices (as described above with respect to FIG. 1), one or more user devices 120 or 220 (including mobile user devices 125 or 225), other electronics devices (as described above with respect to FIG. 1) and/or the like. An advantage of the map view is that, at a glance, the user can easily identify the location of a battery that requires replacement or recharge. Hence, no longer does a user have to hunt down a particular smoke detector or CO detector that is low on battery, by following beeping noises that could be emitted from any of the plurality of detectors. Also, even with user devices that have integrated battery capacity measurement devices that are separate from the wireless capable batteries/wireless capable battery testers as described herein, so long as these user devices are associated with the app or program, and location information is also tracked, the user can easily, at a glance, find missing user devices using the map view.

The user can switch back to the list view by clicking, selecting, depressing, or actuating the “list view” icon or button in the display sub-panel, sub-window, or segment 530. Although the third display sub-panel, sub-window, or segment 545 depicts a floor plan of the user's home, the various embodiments are not so limited, and the third display sub-panel, sub-window, or segment 545 can display a topographical map, a floor plan of a multi-level building, a satellite overlaid map of the area, and/or the like.

In some embodiments, the one or more measured characteristics of the battery might be at least one of received on a periodic basis, received during high performance operation of the equipment (i.e., high battery draw), received during low or no performance operation of the equipment (i.e., low or no battery draw (e.g., during idle periods or the like)), and/or received upon request or update by the user or user interface on the user device. Herein, receiving the measured characteristics of the battery refers to the wireless capable battery or wireless capable battery tester first sending the measured characteristics of the battery during these time periods.

Exemplary System and Hardware Implementation

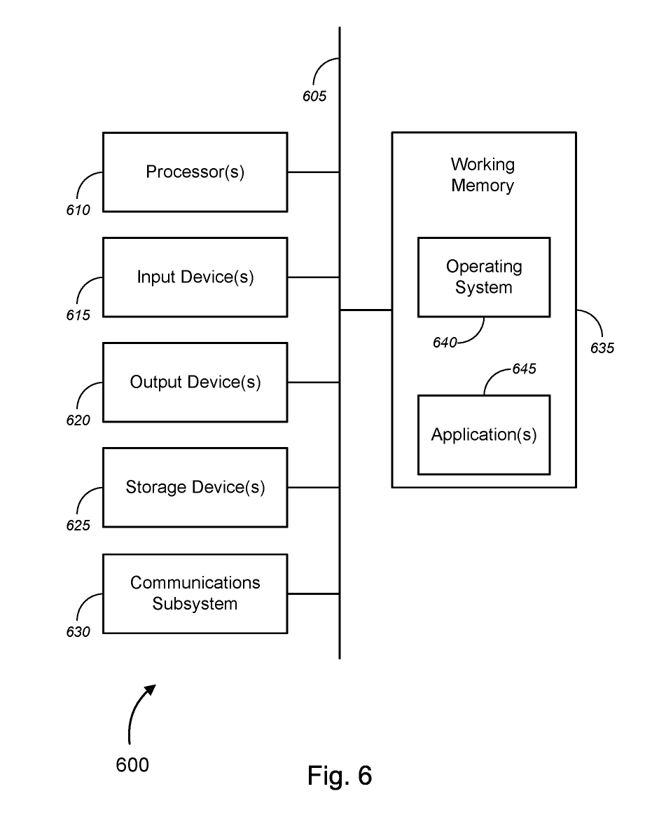

FIG. 6 is a block diagram illustrating an exemplary computer or system hardware architecture, in accordance with various embodiments. FIG. 6 provides a schematic illustration of one embodiment of a computer system 600 of the service provider system hardware that can perform the methods provided by various other embodiments, as described herein, and/or can perform the functions of computer or hardware system (i.e., wireless battery tester 115, 215a, or 215b, processor 160 or 260, wireless capable batteries 305a, 305b, 305c, 305d, 305e, or 305f, user devices 120, 220, or 500, mobile user device 125, 225, or 500, computing system 140 or 240, etc.), as described above. It should be noted that FIG. 6 is meant only to provide a generalized illustration of various components, of which one or more (or none) of each may be utilized as appropriate. FIG. 6, therefore, broadly illustrates how individual system elements may be implemented in a relatively separated or relatively more integrated manner.

The computer or hardware system 600—which might represent an embodiment of the computer or hardware system (i.e., wireless battery tester 115, 215a, or 215b, processor 160 or 260, wireless capable batteries 305a, 305b, 305c, 305d, 305e, or 305f, user devices 120, 220, or 500, mobile user device 125, 225, or 500, computing system 140 or 240, etc.), described above with respect to FIGS. 1-3 and 5—is shown comprising hardware elements that can be electrically coupled via a bus 605 (or may otherwise be in communication, as appropriate). The hardware elements may include one or more processors 610, including, without limitation, one or more general-purpose processors and/or one or more special-purpose processors (such as microprocessors, digital signal processing chips, graphics acceleration processors, and/or the like); one or more input devices 615, which can include, without limitation, a mouse, a keyboard and/or the like; and one or more output devices 620, which can include, without limitation, a display device, a printer, and/or the like.

The computer or hardware system 600 may further include (and/or be in communication with) one or more storage devices 625, which can comprise, without limitation, local and/or network accessible storage, and/or can include, without limitation, a disk drive, a drive array, an optical storage device, solid-state storage device such as a random access memory (“RAM”) and/or a read-only memory (“ROM”), which can be programmable, flash-updateable and/or the like. Such storage devices may be configured to implement any appropriate data stores, including, without limitation, various file systems, database structures, and/or the like.

The computer or hardware system 600 might also include a communications subsystem 630, which can include, without limitation, a modem, a network card (wireless or wired), an infra-red communication device, a wireless communication device and/or chipset (such as a Bluetooth™ device, an 802.11 device, a WiFi device, a WiMax device, a WWAN device, cellular communication facilities, etc.), and/or the like. The communications subsystem 630 may permit data to be exchanged with a network (such as the network described below, to name one example), with other computer or hardware systems, and/or with any other devices described herein. In many embodiments, the computer or hardware system 600 will further comprise a working memory 635, which can include a RAM or ROM device, as described above.

The computer or hardware system 600 also may comprise software elements, shown as being currently located within the working memory 635, including an operating system 640, device drivers, executable libraries, and/or other code, such as one or more application programs 645, which may comprise computer programs provided by various embodiments (including, without limitation, hypervisors, VMs, and the like), and/or may be designed to implement methods, and/or configure systems, provided by other embodiments, as described herein. Merely by way of example, one or more procedures described with respect to the method(s) discussed above might be implemented as code and/or instructions executable by a computer (and/or a processor within a computer); in an aspect, then, such code and/or instructions can be used to configure and/or adapt a general purpose computer (or other device) to perform one or more operations in accordance with the described methods.

A set of these instructions and/or code might be encoded and/or stored on a non-transitory computer readable storage medium, such as the storage device(s) 625 described above. In some cases, the storage medium might be incorporated within a computer system, such as the system 600. In other embodiments, the storage medium might be separate from a computer system (i.e., a removable medium, such as a compact disc, etc.), and/or provided in an installation package, such that the storage medium can be used to program, configure and/or adapt a general purpose computer with the instructions/code stored thereon. These instructions might take the form of executable code, which is executable by the computer or hardware system 600 and/or might take the form of source and/or installable code, which, upon compilation and/or installation on the computer or hardware system 600 (e.g., using any of a variety of generally available compilers, installation programs, compression/decompression utilities, etc.) then takes the form of executable code.

It will be apparent to those skilled in the art that substantial variations may be made in accordance with specific requirements. For example, customized hardware (such as programmable logic controllers, field-programmable gate arrays, application-specific integrated circuits, and/or the like) might also be used, and/or particular elements might be implemented in hardware, software (including portable software, such as applets, etc.), or both. Further, connection to other computing devices such as network input/output devices may be employed.

As mentioned above, in one aspect, some embodiments may employ a computer or hardware system (such as the computer or hardware system 600) to perform methods in accordance with various embodiments of the invention. According to a set of embodiments, some or all of the procedures of such methods are performed by the computer or hardware system 600 in response to processor 610 executing one or more sequences of one or more instructions (which might be incorporated into the operating system 640 and/or other code, such as an application program 645) contained in the working memory 635. Such instructions may be read into the working memory 635 from another computer readable medium, such as one or more of the storage device(s) 625. Merely by way of example, execution of the sequences of instructions contained in the working memory 635 might cause the processor(s) 610 to perform one or more procedures of the methods described herein.

The terms “machine readable medium” and “computer readable medium,” as used herein, refer to any medium that participates in providing data that causes a machine to operate in a specific fashion. In an embodiment implemented using the computer or hardware system 600, various computer readable media might be involved in providing instructions/code to processor(s) 610 for execution and/or might be used to store and/or carry such instructions/code (e.g., as signals). In many implementations, a computer readable medium is a non-transitory, physical, and/or tangible storage medium. In some embodiments, a computer readable medium may take many forms, including, but not limited to, non-volatile media, volatile media, or the like. Non-volatile media includes, for example, optical and/or magnetic disks, such as the storage device(s) 625. Volatile media includes, without limitation, dynamic memory, such as the working memory 635. In some alternative embodiments, a computer readable medium may take the form of transmission media, which includes, without limitation, coaxial cables, copper wire and fiber optics, including the wires that comprise the bus 605, as well as the various components of the communication subsystem 630 (and/or the media by which the communications subsystem 630 provides communication with other devices). In an alternative set of embodiments, transmission media can also take the form of waves (including without limitation radio, acoustic and/or light waves, such as those generated during radio-wave and infra-red data communications).

Common forms of physical and/or tangible computer readable media include, for example, a floppy disk, a flexible disk, a hard disk, magnetic tape, or any other magnetic medium, a CD-ROM, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read instructions and/or code.

Various forms of computer readable media may be involved in carrying one or more sequences of one or more instructions to the processor(s) 610 for execution. Merely by way of example, the instructions may initially be carried on a magnetic disk and/or optical disc of a remote computer. A remote computer might load the instructions into its dynamic memory and send the instructions as signals over a transmission medium to be received and/or executed by the computer or hardware system 600. These signals, which might be in the form of electromagnetic signals, acoustic signals, optical signals, and/or the like, are all examples of carrier waves on which instructions can be encoded, in accordance with various embodiments of the invention.

The communications subsystem 630 (and/or components thereof) generally will receive the signals, and the bus 605 then might carry the signals (and/or the data, instructions, etc. carried by the signals) to the working memory 635, from which the processor(s) 605 retrieves and executes the instructions. The instructions received by the working memory 635 may optionally be stored on a storage device 625 either before or after execution by the processor(s) 610.

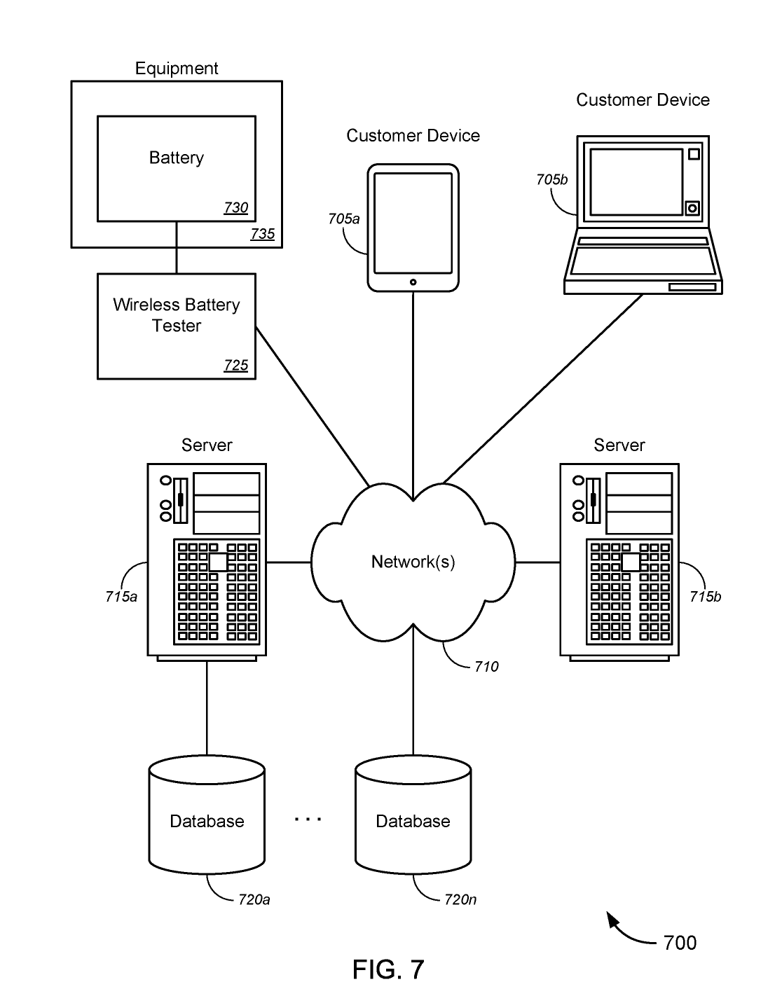

As noted above, a set of embodiments comprises methods and systems for implementing wireless capable batteries or wireless capable battery testers, and, in particular embodiments, to methods, systems, apparatus, and computer software for implementing integrated wireless capable batteries/testers or enabling wireless communication between a battery and/or a battery tester and a user device. FIG. 7 illustrates a schematic diagram of a system 700 that can be used in accordance with one set of embodiments. The system 700 can include one or more user computers, user devices, or customer devices 705. A user computer, user device, or customer device 705 can be a general purpose personal computer (including, merely by way of example, desktop computers, tablet computers, laptop computers, handheld computers, and the like, running any appropriate operating system, several of which are available from vendors such as Apple, Microsoft Corp., and the like), cloud computing devices, a server(s), and/or a workstation computer(s) running any of a variety of commercially-available UNIX™ or UNIX-like operating systems. A user computer, user device, or customer device 705 can also have any of a variety of applications, including one or more applications configured to perform methods provided by various embodiments (as described above, for example), as well as one or more office applications, database client and/or server applications, and/or web browser applications. Alternatively, a user computer, user device, or customer device 705 can be any other electronic device, such as a thin-client computer, Internet-enabled mobile telephone, and/or personal digital assistant, capable of communicating via a network (e.g., the network(s) 710 described below) and/or of displaying and navigating web pages or other types of electronic documents. Although the exemplary system 700 is shown with two user computers, user devices, or customer devices 705, any number of user computers, user devices, or customer devices can be supported.

Certain embodiments operate in a networked environment, which can include a network(s) 710. The network(s) 710 can be any type of network familiar to those skilled in the art that can support data communications using any of a variety of commercially-available (and/or free or proprietary) protocols, including, without limitation, TCP/IP, SNA™, IPX™, AppleTalk™, and the like. Merely by way of example, the network(s) 710 can each include a local area network (“LAN”), including, without limitation, a fiber network, an Ethernet network, a Token-Ring™ network and/or the like; a wide-area network (“WAN”); a wireless wide area network (“WWAN”); a virtual network, such as a virtual private network (“VPN”); the Internet; an intranet; an extranet; a public switched telephone network (“PSTN”); an infra-red network; a wireless network, including, without limitation, a network operating under any of the IEEE 802.11 suite of protocols, the Bluetooth™ protocol known in the art, and/or any other wireless protocol; and/or any combination of these and/or other networks. In a particular embodiment, the network might include an access network of the service provider (e.g., an Internet service provider (“ISP”)). In another embodiment, the network might include a core network of the service provider, and/or the Internet.

Embodiments can also include one or more server computers 715. Each of the server computers 715 may be configured with an operating system, including, without limitation, any of those discussed above, as well as any commercially (or freely) available server operating systems. Each of the servers 715 may also be running one or more applications, which can be configured to provide services to one or more clients 705 and/or other servers 715.

Merely by way of example, one of the servers 715 might be a data server, a web server, a cloud computing device(s), or the like, as described above. The data server might include (or be in communication with) a web server, which can be used, merely by way of example, to process requests for web pages or other electronic documents from user computers 705. The web server can also run a variety of server applications, including HTTP servers, FTP servers, CGI servers, database servers, Java servers, and the like. In some embodiments of the invention, the web server may be configured to serve web pages that can be operated within a web browser on one or more of the user computers 705 to perform methods of the invention.

The server computers 715, in some embodiments, might include one or more application servers, which can be configured with one or more applications accessible by a client running on one or more of the client computers 705 and/or other servers 715. Merely by way of example, the server(s) 715 can be one or more general purpose computers capable of executing programs or scripts in response to the user computers 705 and/or other servers 715, including, without limitation, web applications (which might, in some cases, be configured to perform methods provided by various embodiments). Merely by way of example, a web application can be implemented as one or more scripts or programs written in any suitable programming language, such as Java™, C, C#™ or C++, and/or any scripting language, such as Perl, Python, or TCL, as well as combinations of any programming and/or scripting languages. The application server(s) can also include database servers, including, without limitation, those commercially available from Oracle™, Microsoft™, Sybase™, IBM™, and the like, which can process requests from clients (including, depending on the configuration, dedicated database clients, API clients, web browsers, etc.) running on a user computer, user device, or customer device 705 and/or another server 715. In some embodiments, an application server can perform one or more of the processes for implementing intent-based network services orchestration, or the like, as described in detail above. Data provided by an application server may be formatted as one or more web pages (comprising HTML, JavaScript, etc., for example) and/or may be forwarded to a user computer 705 via a web server (as described above, for example). Similarly, a web server might receive web page requests and/or input data from a user computer 705 and/or forward the web page requests and/or input data to an application server. In some cases, a web server may be integrated with an application server.

In accordance with further embodiments, one or more servers 715 can function as a file server and/or can include one or more of the files (e.g., application code, data files, etc.) necessary to implement various disclosed methods, incorporated by an application running on a user computer 705 and/or another server 715. Alternatively, as those skilled in the art will appreciate, a file server can include all necessary files, allowing such an application to be invoked remotely by a user computer, user device, or customer device 705 and/or server 715.

It should be noted that the functions described with respect to various servers herein (e.g., application server, database server, web server, file server, etc.) can be performed by a single server and/or a plurality of specialized servers, depending on implementation-specific needs and parameters.

In certain embodiments, the system can include one or more databases 720a-720n (collectively, “databases 720”). The location of each of the databases 720 is discretionary: merely by way of example, a database 720a might reside on a storage medium local to (and/or resident in) a server 715a (and/or a user computer, user device, or customer device 705). Alternatively, a database 720n can be remote from any or all of the computers 705, 715, so long as it can be in communication (e.g., via the network 710) with one or more of these. In a particular set of embodiments, a database 720 can reside in a storage-area network (“SAN”) familiar to those skilled in the art. (Likewise, any necessary files for performing the functions attributed to the computers 705, 715 can be stored locally on the respective computer and/or remotely, as appropriate.) In one set of embodiments, the database 720 can be a relational database, such as an Oracle database, that is adapted to store, update, and retrieve data in response to SQL-formatted commands. The database might be controlled and/or maintained by a database server, as described above, for example.

According to some embodiments, system 700 might further comprise a wireless capable battery tester(s) 725 (similar to wireless battery tester 115, 215a, or 215b of FIG. 1 or 2, or wireless capable batteries 305a, 305b, 305c, 305d, 305e, or 305f of FIG. 3, or the like), a battery or a set/plurality of batteries 730 (similar to batteries 110 or 210 of FIG. 1 or 2, or the like), and/or one or more equipment or devices 735 (similar to equipment 105 or 205 of FIG. 1 or 2; telecommunications equipment 325 of FIG. 3A; vehicle 330 or 550 of FIG. 3B or 5D; clock 340 or 555, smoke detector 345 or 560, CO detector 350 or 565, or street lamp 365 of FIG. 3C or 5D; and/or the like), as described in detail above with respect to FIGS. 1-5. In some embodiments, wireless capable battery tester 725 might be one of integrated within battery 730 (as shown in FIG. 1), external to the battery 730 yet housed within the equipment 735 (as shown in FIG. 2), or external to both the battery 730 and the equipment 735 yet coupled to battery 730 (as also shown in FIG. 2).

While certain features and aspects have been described with respect to exemplary embodiments, one skilled in the art will recognize that numerous modifications are possible. For example, the methods and processes described herein may be implemented using hardware components, software components, and/or any combination thereof. Further, while various methods and processes described herein may be described with respect to particular structural and/or functional components for ease of description, methods provided by various embodiments are not limited to any particular structural and/or functional architecture but instead can be implemented on any suitable hardware, firmware and/or software configuration. Similarly, while certain functionality is ascribed to certain system components, unless the context dictates otherwise, this functionality can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with—or without—certain features for ease of description and to illustrate exemplary aspects of those embodiments, the various components and/or features described herein with respect to a particular embodiment can be substituted, added and/or subtracted from among other described embodiments, unless the context dictates otherwise. Consequently, although several exemplary embodiments are described above, it will be appreciated that the invention is intended to cover all modifications and equivalents within the scope of the following claims.

What is claimed is:

1. A method, comprising:
receiving, with a processor of a wireless capable battery tester and from one or more sensors of the wireless capable battery tester, one or more measured characteristics of a battery;
wirelessly sending, with the processor via a wireless transceiver of the wireless capable battery tester, the one or more measured characteristics of the battery to one or more user devices.

2. The method of claim 1, wherein the wireless capable battery tester is integrated within the battery.

3. The method of claim 1, wherein the wireless capable battery tester is external to the battery, and at least one of the one or more sensors is coupled to the battery.

4. The method of claim 1, wherein the one or more sensors include at least one sensor selected from a group consisting of a voltmeter, an ammeter, a thermometer, and a location sensor.

5. The method of claim 1, wherein wirelessly sending the one or more measured characteristics of the battery to one or more user devices comprises wirelessly sending, with the processor via the wireless transceiver, the one or more measured characteristics of the battery to one or more user devices using one of Bluetooth protocol, long term evolution (“LTE”) protocol, unlicensed LTE (“LTE-U”) protocol, Wi-Fi protocol, controller area network bus (“CAN bus”) protocol, or 900 MHz band protocol.

6. The method of claim 1, wherein wirelessly sending the one or more measured characteristics of the battery to one or more user devices comprises:
wirelessly sending, with the processor via the wireless transceiver, the one or more measured characteristics of the battery to a server over a network;
analyzing, with the server, the one or more measured characteristics of the battery by comparing, with the server, each of the one or more measured characteristics of the battery with corresponding one or more battery characteristics of a battery of the same model or type that are stored in at least one database; and
sending, with the server, one or more analyzed characteristics of the battery to the one or more user devices over the network.

7. The method of claim 1, wherein the one or more user devices comprises at least one of a tablet computer, a smart phone, a mobile phone, a portable gaming device, a laptop computer, or a desktop computer.

8. The method of claim 1, wherein the battery is one of a telecommunications equipment battery within a battery string providing power to telecommunications equipment in a central office or remote cabinet, a battery string providing power to telecommunications equipment in a central office or remote cabinet, a car battery, a boat battery, an aircraft battery, a space station battery, a spacecraft battery, a satellite battery, a consumer electronics battery, a clock battery, a smoke detector battery, a carbon monoxide (“CO”) detector battery, a solar-powered street lamp battery, a solar-powered garden light battery, an electronics backup battery, a marine beacon battery, a seismograph battery, or a weather station battery.

9. A wireless capable battery tester, comprising:
one or more sensors;
at least one transceiver;
at least one processor communicatively coupled to each of the one or more sensors and the at least one transceiver; and
a non-transitory computer readable medium communicatively coupled to the at least one processor, the non-transitory computer readable medium having stored thereon computer software comprising a set of instructions that, when executed by the at least one processor, causes the wireless capable battery tester to:
receive, from the one or more sensors, one or more measured characteristics of a battery that the wireless capable battery tester is testing;
wirelessly send, via the at least one transceiver, the one or more measured characteristics of the battery to one or more user devices.

10. The wireless capable battery tester of claim 9, wherein the wireless capable battery tester is integrated within the battery.

11. The wireless capable battery tester of claim 9, wherein the wireless capable battery tester is external to the battery, and at least one of the one or more sensors is coupled to the battery.

12. The wireless capable battery tester of claim 9, wherein the one or more sensors include at least one sensor selected from a group consisting of a voltmeter, an ammeter, a thermometer, and a location sensor.

13. The wireless capable battery tester of claim 9, wherein wirelessly sending the one or more measured characteristics of the battery to one or more user devices comprises wirelessly sending, via the wireless transceiver, the one or more measured characteristics of the battery to one or more user devices using one of Bluetooth protocol, long term evolution (“LTE”) protocol, unlicensed LTE (“LTE-U”) protocol, Wi-Fi protocol, controller area network bus (“CAN bus”) protocol, or 900 MHz band protocol.

14. The wireless capable battery tester of claim 9, wherein the set of instructions, when executed by the at least one processor, further causes the wireless capable battery tester to:
wirelessly send, via the wireless transceiver, the one or more measured characteristics of the battery to a server over a network, wherein the server analyzes the one or more measured characteristics of the battery by comparing each of the one or more measured characteristics of the battery with corresponding one or more battery characteristics of a battery of the same model or type that are stored in at least one database, and wherein the server sends one or more analyzed characteristics of the battery to the one or more user devices over the network.

15. The wireless capable battery tester of claim 9, wherein the one or more user devices comprises at least one of a tablet computer, a smart phone, a mobile phone, a portable gaming device, a laptop computer, or a desktop computer.

16. The wireless capable battery tester of claim 9, wherein the battery is one of a telecommunications equipment battery within a battery string providing power to telecommunications equipment in a central office or remote cabinet, a battery string providing power to telecommunications equipment in a central office or remote cabinet, a car battery, a boat battery, an aircraft battery, a space station battery, a spacecraft battery, a satellite battery, a consumer electronics battery, a clock battery, a smoke detector battery, a carbon monoxide (“CO”) detector battery, a solar-powered street lamp battery, a solar-powered garden light battery, an electronics backup battery, a marine beacon battery, a seismograph battery, or a weather station battery.

17. A method, comprising:
wirelessly receiving, with a processor of a user device via a wireless transceiver of the user device, one or more characteristics of a battery as measured by a wireless capable battery tester; and
displaying, with the processor and on a display screen of the user device, a user interface, the user interface presenting the one or more characteristics of the battery.

18. The method of claim 17, wherein the one or more characteristics of the battery include at least one of voltage, amperage, or temperature of the battery.

19. The method of claim 17, further comprising:
calculating, with the processor, at least one of a current percentage of remaining battery charge, an estimated remaining life, or a current overall condition of the battery, based at least in part on the one or more characteristics of the battery; and
displaying, via the user interface, the calculated at least one of the current percentage of remaining battery charge, the estimated remaining life, or the current overall condition of the battery.

20. The method of claim 19, further comprising at least one of:
based on the calculated current percentage of remaining battery charge of the battery, displaying a notification indicating to recharge the battery; or
based on the calculated estimated remaining life of the battery, displaying a notification indicating to replace the battery.

21. The method of claim 20, wherein the one or more characteristics further comprises a location of the battery, and wherein the method further comprises:
displaying, via the user interface, the location of the battery.

22. The method of claim 17, further comprising:
wirelessly receiving, with the processor via the wireless transceiver of the user device, one or more characteristics of each of a plurality of second batteries as measured by one or more wireless capable battery testers; and
displaying, with the processor via the user interface, the one or more characteristics of each of the plurality of second batteries.
